(19) United States
(12) Patent Application Publication
(10) Pub. No.: US 2025/0191890 A1
(43) Pub. Date: Jun. 12, 2025

(54) SHIELDING PLASMA ETCHING DATA COLLECTION WINDOWS USING POSITIVELY CHARGED CONDUCTIVE FILMS

(71) Applicant: International Business Machines Corporation, Armonk, NY (US)

(72) Inventors: Viswas Purohit, East Amherst, NY (US); Tao Li, Slingerlands, NY (US); Yann Mignot, Slingerlands, NY (US); Sarah El-Helw, Albany, NY (US); Shravana Kumar Katakam, Lehi, UT (US); Genevieve Beique, Latham, NY (US); Brian Conerney, Ballston Lake, NY (US)

(21) Appl. No.: 18/531,857

(22) Filed: Dec. 7, 2023

(51) Int. Cl. H01J 37/32

(52) U.S. Cl. CPC H01J 37/32495; H01J 37/32807; H01J 37/32972; H01J 37/3299; H01J 2237/2482; H01J 2237/285; H01J 2237/3341

(57) ABSTRACT

A plasma etching system includes a reaction chamber configured to react plasma with a substrate to perform an etching process, and a chamber port providing visual access to an internal area of the reaction chamber. A chamber port assembly is disposed in the chamber port and is configured to generate an electric field in response to receiving a voltage. The plasma etching system can also repel plasma ions by forming an electrically conductive transparent window-protective film on surface of a data collection window, and disposing the data collection window in a chamber port of a plasma etching system. A voltage can then be applied to the electrically conductive transparent window-protective film to generate an electric field. A plasma etching process can then be performed in the reaction chamber and the plasma ions produced during the etching process are repelled away from the data collection window via the electric field.

### BACKGROUND

The present disclosure generally relates to semiconductor fabrication processing, and more specifically, to the protection of a plasma etching data collection window included in a plasma reaction chamber.

Semiconductor plasma etching is a common process in the fabrication of electronic devices, particularly in the manufacturing of integrated circuits and microelectronic components. This technique involves the use of a highly ionized gas (typically referred to as “plasma”), which contains positively charged ions and free electrons. The plasma can be utilized to selectively remove material from a semiconductor wafer. The process begins by placing the wafer in a reaction chamber and introducing a specific combination of gases, typically including halogen-based gases like fluorocarbons or chlorine. An electric field is then applied, which ionizes these gases to form the plasma. The plasma generates reactive species, such as ions and radicals, which interact with the surface of the wafer. These reactive species physically and chemically etch away specific regions of a targeted material, guided by a patterned mask applied to the wafer's surface. This mask, often made of a photolithographic material, protects certain areas of the wafer while exposing others to the etching process.

The reactor chamber is designed to maintain a controlled environment for the plasma generation when performing the etching process. The chamber is equipped with electrodes to generate the electric field necessary for ionizing the gas into plasma and operates according to a control system, which monitors and regulates parameters such as gas flow rates, pressure, and temperature. The reactor chamber can further employ a data collection window that allows for real-time monitoring and analysis of the etching process. Accordingly, the data collection window can provide a visual or optical access point into the chamber. Through this window, various optical diagnostic tools such as optical emission spectroscopy and similar can be used to gather data about the plasma and the etching process.

### SUMMARY

In a plasma etching system, operational efficiency and accuracy are crucial. This system includes a reaction chamber designed for engaging plasma with a substrate for etching purposes. A significant challenge in such systems is maintaining clear visual access to the reaction chamber's internal area, essential for monitoring and controlling the etching process. To address this, the system is equipped with a chamber port, through which the internal area of the reaction chamber can be observed. Integrated into this chamber port is a specialized chamber port assembly. This assembly is uniquely designed to generate an electric field upon receiving a voltage. The application of this electric field is pivotal; it actively repels contaminants and charged particles, thereby preventing the accumulation of deposits and ion-induced etching on the port. This innovation ensures sustained visual clarity and, consequently, enhances the precision and effectiveness of the plasma etching process.

According to a non-limiting embodiment, a plasma etching system includes a reaction chamber configured to react plasma with a substrate to perform an etching process, and a chamber port providing visual access to an internal area of the reaction chamber. A chamber port assembly is disposed in the chamber port. The chamber port assembly is configured to generate an electric field in response to receiving a voltage.

According to another non-limiting embodiment, a chamber port assembly comprises a chamber port defining a port opening. A transparent data collection window is disposed in the port opening, and a window-protective film is disposed on the transparent data collection window. The window-protective film comprises an electrically conductive transparent material configured to convey electromagnetic energy therethrough and to conduct electricity.

According to yet another non-limiting embodiment, a method of preserving a data collection window included in a plasma etching system is provided. The method comprises forming an electrically conductive transparent window-protective film on surface of a data collection window, and disposing the data collection window having the electrically conductive transparent window-protective film formed thereon in a chamber port of a plasma etching system. The method further comprises applying a voltage to the electrically conductive transparent window-protective film, and generating an electric field from the window-protective film in response to the voltage. The method further comprises performing a plasma etching process in a reaction chamber of the plasma etching system, and repelling plasma ions produced during the plasma etching process away from the data collection window via the electric field.

Other embodiments of the present disclosure implement features of the above-described devices/structures in methods and/or implement features of the methods in devices/structures.

Additional technical features and benefits are realized through the techniques of the present disclosure. Embodiments and aspects of the disclosure are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the disclosure are apparent from the following detailed description taken in conjunction with the accompanying drawings in which:

FIG. 1 is a block diagram of a plasma etching system according to a non-limiting embodiment of the present disclosure;

FIG. 2A is a separated view of a chamber port assembly depicted in a first orientation according to a non-limiting embodiment of the present disclosure;

FIG. 2B is a separated view of the chamber port assembly shown in FIG. 2A depicted in a second orientation according to a non-limiting embodiment of the present disclosure;

FIG. 2C is a front perspective view of a chamber port assembly according to a non-limiting embodiment of the present disclosure;

FIG. 2D is a rear perspective view of the chamber port assembly shown in FIG. 2C according to a non-limiting embodiment according to a non-limiting embodiment of the present disclosure;

FIG. 2E is a cross-sectional view of the chamber port assembly shown in FIG. 2C taken along line A-A according to a non-limiting embodiment of the present disclosure;

FIG. 2F depict rear and front perspective of a chamber port assembly according to a non-limiting embodiment of the present disclosure; and

FIG. 3 is a flow diagram illustrating a method of preserving a data collection window included in a plasma etching system according to a non-limiting embodiment of the present disclosure.

### DETAILED DESCRIPTION

During the semiconductor etching process, the plasma interaction with different materials produces energy in the form of light, and the wavelength of the light is unique to the type of material being etched. This light is directed through data collection window, which is typically formed of quartz, and is detected by an optical emission spectroscopy (OES) tool. In this manner, the different wavelengths of light can be detected and the different layers of materials being etched and/or the etching endpoint of a targeted layer of material can be identified.

Over time, however, the plasma etching process can etch the surface of the quartz data collection window, leading to a decrease in the intensity of the collected light. The decrease in light intensity can compromise the accuracy of the current material being etched and/or the etching endpoint detection, making it difficult to determine when the targeted etching is complete and increasing the risk of over-etching. The etching or damage of the quartz data collection window also shortens the time between necessary cleanings and/or replacement of the window, thereby impacting the overall maintenance cycle.

Various non-limiting embodiments addresses the short-comings of conventional plasma etching systems by providing a plasma etching system that employs a chamber port assembly configured to preserve the data collection window from damage caused by the plasma etching process. According to a non-limiting embodiment, the chamber port assembly includes a data collection window having an electrically conductive transparent window-protective film formed thereon. The window protective film is configured to generate an electric field in response to receiving an applied voltage. The electric field repels like-charged plasma ions away from the data collection window, thereby reducing, or even completely preventing, the data collection window collection from damage caused by the plasma etching process.

Accordingly, by reducing the ion bombardment and interaction with reactive species, the window protective film can help to preserve the material of the data collection window to enhance the window's longevity, maintain the accuracy of data collection, and reduce the frequency of cleaning or replacement required. The window protective film also assists in maintaining the window's optical transparency and the integrity of its surface, allowing for better and more consistent performance and data collection capabilities (e.g., using an OES tool) over time.

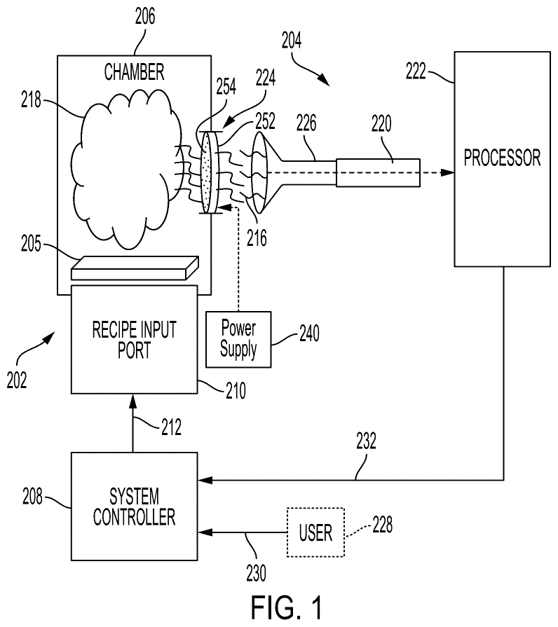

With reference now to FIG. 1, a plasma etching system 202 and a process monitoring system 204 are illustrated according to a non-limiting embodiment of the present disclosure. The plasma etching system 202 comprises a plasma reaction chamber 206 in signal communication with a plasma processing system controller 208 via a recipe input port 210 and via a first control bus 212 or other suitable interface and a process monitoring system 204.

The reaction chamber 206 employs a chamber port assembly 224, which is disposed in a viewing port or port opening (e.g. formed in a wall of the reaction chamber 206) that provides access to an internal area of reaction chamber 206 which perform the plasma etching process. The chamber port assembly 224 includes an electrically conductive transparent window-protective film 254 disposed on a transparent data collection window 252 for conveying electromagnetic emissions 216 from the inside of the chamber 206 to the outside of the chamber 206. According to a non-limiting embodiment, the window-protective film 254 is disposed on a rear side of the transparent data collection window 252 facing the internal area of the reaction chamber 206, and an OES tool can be disposed on a front side of the transparent data collection window 252 opposite the rear side. In at least one non-limiting embodiment, the window-protective film 254 and the rear side of the data collection window 252 is disposed inside the reaction chamber 206, while the front side of the data collection window 252 is located on an outside (e.g., externally) of the reaction chamber 206 and sealed from the inside area of the reaction chamber 206.

The emissions 216 are primarily optical wavelengths (e.g., light). The emissions 216 are produced by plasma 218 sustained within the reaction chamber 206. The plasma electromagnetic emissions 216 can be produced from a large number of plasma species (e.g., process gasses, reaction products, etc.). Although the chamber port assembly 224 is shown installed on the side of the reaction chamber 206, it should be appreciated that the chamber port assembly 224 can be installed at any other location (e.g., on the top or bottom of the chamber 206) without departing from the scope of the disclosure.

The process monitoring system 204 includes an OEM tool 220 coupled to a processor 222 in communication with the system controller 208 via interface 232. The OEM tool 220 is positioned with respect to the chamber port assembly 224 to collect the electromagnetic emissions 216 emitted by the plasma 218 and to provide intensity information regarding a plurality of plasma electromagnetic emission wavelengths to the processor 222.

The plasma processing controller receives a set of instructions (sometimes referred to as a “plasma recipe”) for generating the plasma 218 within the reaction chamber 206. A typical plasma recipe includes processing parameters such as the pressure, temperature, power, gas types, gas flow rates and the like used to initiate and maintain the plasma 218 within the reaction chamber 206 during plasma processing. According to a non-limiting embodiment, a user 228 (e.g., a person in charge of a wafer fabrication process) can deliver the plasma recipe to the plasma processing system controller 208 via a second control bus 230 or other suitable interface. In some embodiments, a remote computer system (not shown) can control a fabrication process, and can supply the plasma processing system controller 208 with a plasma recipe (e.g., as supplied by the user 228 or as stored within a plasma recipe database). Once the plasma processing system controller 208 receives a plasma recipe the plasma recipe is supplied to the recipe input port 210 via the first control bus 212, and the recipe input port 210 (or the plasma processing system controller 208 itself if the recipe input port 210 is not present) establishes and maintains within the reaction chamber 206 the processing parameters specified by the plasma recipe.

During a plasma process within the reaction chamber 206, the plasma 218 generates electromagnetic emissions 216 having wavelengths corresponding to the current material or layer of material being etched within the chamber 206. A portion of these electromagnetic emissions (e.g., the electromagnetic emissions 216) travels through the chamber port assembly 224 and reaches the inventive process monitoring system 204.

The OEM tool 220 receives the electromagnetic emissions 216 via the chamber port assembly 224 and the fiber optic cable 226. In response thereto, the OEM tool 220 spatially separates the electromagnetic emissions 216 based on wavelength (e.g., via a prism or a diffraction grating, and generates detection signals (e.g., detection currents) for a plurality of the spatially separated wavelengths. The processor 222 continually monitors the detection signals from the OEM tool 220 and provides feedback to the system controller 208 and/or the user 228 about the plasma state. The user 228 and/or system controller 208 can adjust the processing parameters to maintain the plasma 218 in a steady state.

With continued reference to FIG. 1, the plasma etching system 202 includes a power supply 240 in signal communication with the chamber port assembly 224. The power supply 240 outputs a voltage (+ve), which is delivered to the electrically conductive transparent window-protective film 254, either according to a constant power deliver or a pulsed power delivery. In response to receiving the voltage, the electrically conductive transparent window-protective film 254 generates an electric field, which repels the ions (e.g., positive ions) included in the plasma 218. Since like charges repel, the positive voltage bias (+ve) applied to the electrically conductive transparent window-protective film 254 repels the positively charged ions in the plasma 218. The resulting repulsion prevents the plasma ions from reaching the window surface and thus limits the damage or contamination to the data collection window 252. Although FIG. 1 shows a positive voltage bias (+ve) being applied to the electrically conductive transparent window-protective film 254 when the plasma 218 contains positive ions, it should be appreciated that a positive voltage bias (+ve) can be applied to the electrically conductive transparent window-protective film 254 when the plasma 218 contains negative ions.

As described herein, the electrically conductive transparent window-protective film 254 prevents the plasma ions from reaching the underly surface of the data collection window 252, thereby limiting, or fully preventing, damage or contamination during the plasma etching process. The electrically conductive transparent window-protective film 254 can also reduce secondary electron emission from the data collection window 252, thereby preventing further ionization and potentially enhance plasma-surface interactions the material (e.g., quartz) the data collection window 252.

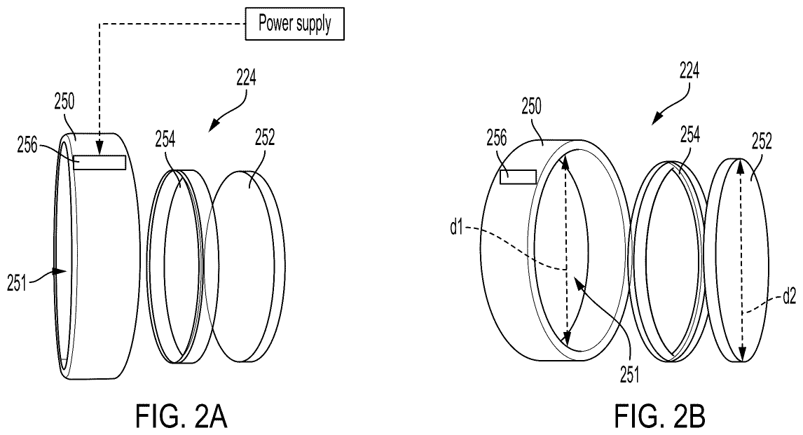

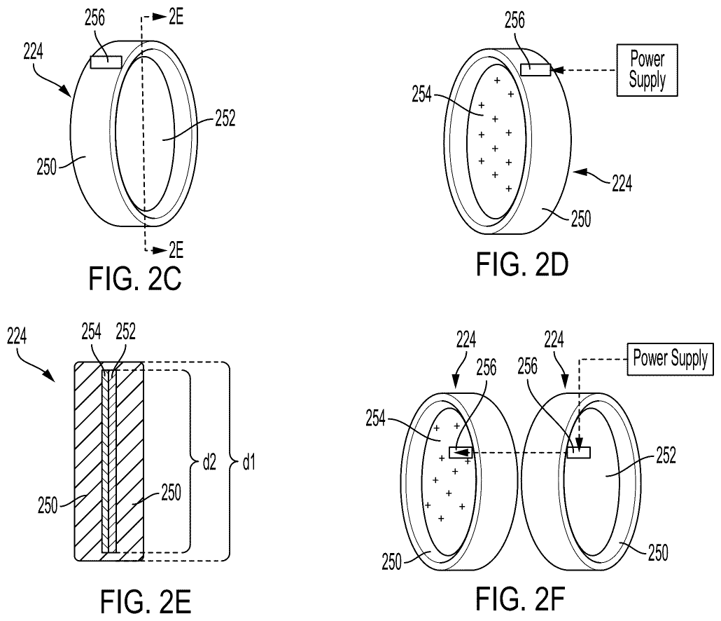

Turning now to FIGS. 2A, 2B, 2C, 2D and 2E (collectively referred to as FIGS. 2A-2E), a chamber port assembly 224 that can be implemented in the plasma etching system 202 is illustrated according to a non-limiting embodiment of the present disclosure. The chamber port assembly 224 is configured to generate an electric field (+) in response to receiving the voltage (e.g., +ve) from a power supply 240 (see e.g., FIG. 2D). Accordingly, the chamber port assembly 224 can transmit energy (e.g., light) therethrough while repelling ions (e.g., positive ions) included in the plasma 218 contained in the plasma etching system 202 away from the chamber port assembly 224.

The chamber port assembly 224 includes a chamber port 250, a data collection window 252, and a window-protective film 254. The chamber port 250 can be formed of any electrically conductive material (e.g., copper, tin, aluminum, etc.) and has an annular-shaped port housing that defines a port opening 251. According to a non-limiting embodiment, the port opening 251 the port opening 251 can be implemented as a ConFlat (CF), a KF (QF) flange type window or similar flange type window. The port opening 251 can have a port opening (e.g., diameter) ranging, for example, from about 1.0 inches (in) to about 3.0 inches. In some non-limiting embodiments, the width of the port opening 251 can be any of the following of 1.18 in, 1.57 in, 2.16 in or 2.95 in The chamber port 250 further includes an electrically conductive electrode 256 that can be formed from any electrically conductive material (e.g., copper, tin, aluminum, etc.) capable of establishing signal communication with the power supply 240 (e.g., via a signal line) to receive the output bias voltage (e.g., +ve).

The data collection window 252 can be formed from a transparent material such as quartz, for example, and has a circular shape defining a second diameter (d2) that is less than the first diameter (d1). The data collection window 252 is disposed in the port opening 251 and is secured therein by the chamber port 250. According to a non-limiting embodiment, an adhesive film is disposed on the inner surface of the chamber port 250 and/or the outer edge of the data collection window 252 to affix the data collection window 252 in the chamber port 250.

The window-protective film 254 is disposed on the data collection window 252. The window-protective film 254 is formed from an electrically conductive transparent material configured to convey (e.g., transmit) electromagnetic energy (e.g. light) therethrough and also establish electrical conductivity with the chamber port 250. According to a non-limiting embodiment, the electrically conductive transparent material includes, but is not limited to, indium tin oxide (ITO), fluorine-doped tin oxide (FTO), aluminum-doped zinc oxide (AZO), graphene, or any other material having optical transparency, conduct electricity, and block charged ions in the plasma 218 from reaching the data collection window 252 and/or reducing the window's interaction with neutral reactive species in the plasma 218. Various deposition methods including, but not limited to, atomic layer deposition (ALD), chemical vapor deposition (CVD) and sputtering can be used to form or deposit the window-protective film 254 on the surface of the data collection window 252.

Referring to FIG. 2F, another non-limiting embodiment of the present disclosure couples at least a portion of an electrode 256 to the window-protective film 254. In this manner, the electrode 256 can establish direct electrical conductivity with the power supply 240 (e.g., via a signal wire). For example, a first portion of the electrode 256 can be disposed on the surface of the window-protective film 254 and a second portion of the electrode 256 extends from the first portion and can be disposed on the surface of the data collection window 252. In this manner, voltage applied to the second portion of the electrode 256 accessible on the data collection window 252 can be delivered to the first portion of the electrode 256, and thus applied to the window-protective film 254 to generate the electric field (+).

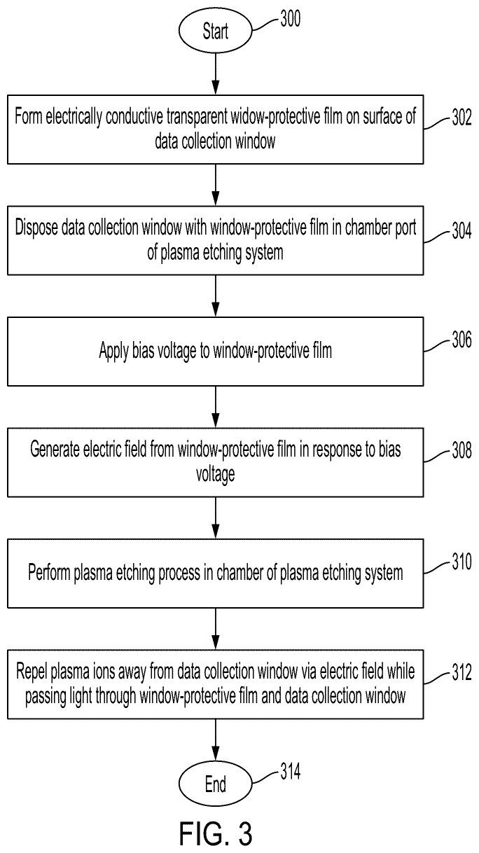

Referring to FIG. 3, a method of preserving a data collection window included in a plasma data chamber (e.g., the chamber port assembly 224) is illustrated according to a non-limiting embodiment of the present disclosure. The method begins at operation 300, and at operation 302 an electrically conductive transparent window-protective film is formed or deposited on the surface (e.g., inner surface) of data collection window facing the internal area of plasma etching system chamber. At operation 304, the data collection window having the electrically conductive transparent window-protective film formed thereon is disposed in a chamber port of the plasma etching system. At operation 306, a bias voltage (e.g., +ve) is applied to the electrically conductive transparent window-protective film. As described herein, the bias voltage can be applied by a power supply that is electrically connected to the electrically conductive transparent window-protective film.

At operation 308, an electric field is generated from the electrically conductive transparent window-protective film in response to applying the bias voltage. At operation 310, a plasma etching process is performed using a plasma supply contained in the reaction chamber. According to a non-limiting embodiment, the electrical charge of the bias voltage is selected to match the electrical charge of plasma ions. For example, if plasma used for the etching process contains positively charged ions, than a negative bias voltage is supplied by the power supply and applied to the electrically conductive transparent window-protective film. At operation 312, the plasma ions are repelled away from data collection window via the electric field, while energy (e.g. light) generated during the etching process passes through the window-protective film and the data collection window, and the method ends at operation 314.

As described herein, various non-limiting embodiments of the present disclosure provides a plasma etching system that employs a plasm ion-repelling chamber port assembly. The chamber port assembly includes a data collection window having a window-protective film formed thereon. When applying a voltage to the window-protective film, it generates an electric field that repels plasma ions from reaching the underlying surface of the data collection window. Accordingly, the window-protective film can serve as a protective barrier that can reduce, or even prevent, window degradation due to ion-induced etching and/or contaminant accumulation.

Various embodiments of the present disclosure are described herein with reference to the related drawings. Alternative embodiments can be devised without departing from the scope of this disclosure. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The phrase “selective to,” such as, for example, “a first element selective to a second element,” means that the first element can be etched and the second element can act as an etch stop.

For the sake of brevity, conventional techniques related to making and using aspects of the disclosure may or may not be described in detail herein. In particular, various aspects of computing systems and specific computer programs to implement the various technical features described herein are well known. Accordingly, in the interest of brevity, many conventional implementation details are only mentioned briefly herein or are omitted entirely without providing the well-known system and/or process details.

In some embodiments, various functions or acts can take place at a given location and/or in connection with the operation of one or more apparatuses or systems. In some embodiments, a portion of a given function or act can be performed at a first device or location, and the remainder of the function or act can be performed at one or more additional devices or locations.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The present disclosure has been presented for purposes of illustration and description but is not intended to be exhaustive or limited to the form disclosed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the disclosure for various embodiments with various modifications as are suited to the particular use contemplated.

The diagrams depicted herein are illustrative. There can be many variations to the diagram or the steps (or operations) described therein without departing from the spirit of the disclosure. For instance, the actions can be performed in a differing order or actions can be added, deleted or modified. Also, the term “coupled” describes having a signal path between two elements and does not imply a direct connection between the elements with no intervening elements/connections therebetween. All of these variations are considered a part of the present disclosure.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e., one, two, three, four, etc. The terms “a plurality” are understood to include any integer number greater than or equal to two, i.e., two, three, four, five, etc. The term “connection” can include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A plasma etching system comprising:
a reaction chamber configured to react plasma with a substrate to perform an etching process;
a chamber port providing visual access to an internal area of the reaction chamber;
a chamber port assembly disposed in the chamber port, the chamber port assembly configured to generate an electric field in response to receiving a voltage.

2. The plasma etching system of claim 1, wherein the electric field repels ions included in the plasma away from the chamber port assembly.

3. The plasma etching system of claim 1, wherein the chamber port assembly comprises:
a chamber port defining a port opening;
a transparent data collection window disposed in the port opening, the transparent data collection window having a rear side facing the internal area of the reaction chamber and a front side opposite the rear side facing an exterior of the reaction chamber; and
a window-protective film disposed on the rear side of the transparent data collection window, the window-protective film comprising an electrically conductive transparent material configured to convey electromagnetic energy therethrough and to conduct electricity.

4. The plasma etching system of claim 3, wherein the window-protective film is disposed on a rear side of the transparent data collection window facing the internal area of the reaction chamber.

5. The plasma etching system of claim 4, further comprising an optical emission spectroscopy (OES) tool disposed adjacent the front side of the transparent data collection window.

6. The plasma etching system of claim 3, further comprising a power supply in signal communication with the window-protective film, the power supply configured to deliver the voltage to the transparent data collection window.

7. The plasma etching system of claim 6, wherein the electrically conductive transparent material comprises at least one of indium tin oxide (ITO), fluorine-doped tin oxide (FTO), aluminum-doped zinc oxide (AZO), and graphene.

8. A chamber port assembly comprising:
a chamber port defining a port opening;
a transparent data collection window disposed in the port opening; and
a window-protective film disposed on the transparent data collection window, the window-protective film comprising an electrically conductive transparent material configured to convey electromagnetic energy therethrough and to conduct electricity.

9. The chamber port assembly of claim 8, wherein the window-protective film produces an electric field in response to receiving a voltage.

10. The chamber port assembly of claim 9, wherein the electrically conductive transparent material comprises at least one of indium tin oxide (ITO), fluorine-doped tin oxide (FTO), aluminum-doped zinc oxide (AZO), graphene.

11. The chamber port assembly of claim 10, wherein the transparent data collection window comprises quartz.

12. The chamber port assembly of claim 10, wherein the chamber port has an annular-shaped port defining a first diameter of the port opening, and the transparent data collection window has a circular shape defining a second diameter that is less than the first diameter.

13. The chamber port assembly of claim 10, wherein the chamber port comprises an electrically conductive material and includes an electrically conductive electrode disposed on the chamber port, wherein the electrically conductive electrode establishes electrical conductivity between the window-protective film and a power supply configured to supply the voltage.

14. The chamber port assembly of claim 10, wherein the window-protective film includes an electrically conductive electrode having a first portion disposed on the window-protective film and a second portion extending from the first portion and disposed on the transparent data collection window, the second portion configured to establish electrical conductivity with a power supply that generates the voltage and to deliver the voltage to the window-protective film via the first portion.

15. A method of preserving a data collection window included in a plasma etching system, the method comprising:
forming an electrically conductive transparent window-protective film on surface of a data collection window;
disposing the data collection window having the electrically conductive transparent window-protective film formed thereon in a chamber port of a plasma etching system;
applying a voltage to the electrically conductive transparent window-protective film;
generating an electric field from the window-protective film in response to the voltage;
performing a plasma etching process in a reaction chamber of the plasma etching system; and
repelling plasma ions produced during the plasma etching process away from the data collection window via the electric field.

16. The method of claim 15, further comprising passing light through the electrically conductive transparent window-protective film and the data collection window, while repelling the plasma ions.

17. The method of claim 15, wherein the forming the electrically conductive transparent window-protective film the surface of the data collection window includes performing at least one of an atomic layer deposition (ALD) process, a chemical vapor deposition (CVD) process, and a sputtering process.

18. The method of claim 17, wherein the forming the electrically conductive transparent window-protective film the surface of the data collection window includes depositing at least one of indium tin oxide (ITO), fluorine-doped tin oxide (FTO), aluminum-doped zinc oxide (AZO), and graphene.

19. The method of claim 15, wherein applying the voltage includes applying a positive bias voltage when the plasma etching process utilizes positively charged ions.

20. The method of claim 15, wherein applying the voltage includes applying a negative bias voltage when the plasma etching process utilizes negatively charged ions.
